(19) United States
(12) Patent Application Publication
(10) Pub. No.: US 2012/0299078 A1
(43) Pub. Date: Nov. 29, 2012

(54) SEMICONDUCTOR STORAGE DEVICE AND MANUFACTURING METHOD THEREOF

(75) Inventors: Hiroshi KAMEI, Kanagawa-ken (JP); Saori SHIMMEI, Kanagawa-ken (JP); Norio OHTANI, Kanagawa-ken (JP)

(73) Assignee: Kabushiki Kaisha Toshiba, Tokyo (JP)

(21) Appl. No.: 13/419,994

(22) Filed: Mar. 14, 2012

(30) Foreign Application Priority Data
May 25, 2011 (JP) 2011-116780

(51) Int. Cl. H01L 29/78; H01L 21/336

(52) U.S. Cl. 257/314; 438/303; 257/E29.255; 257/E21.409

(57) ABSTRACT

According to one embodiment, there is disclosed a semiconductor storage device comprising a semiconductor substrate and a plurality of electrical rewritable nonvolatile memory cells. Each of the memory cells includes a floating gate and a control gate on the semiconductor substrate. Each of the memory cells shares a source/drain region with an adjacent memory cell. The memory cells are connected serially and configure a NAND cell unit. The source/drain region includes silicide layer.

### CROSS-REFERENCE TO RELATED APPLICATIONS

This application is based upon and claims the benefit of priority from the prior Japanese Patent Application No. 2012-116780, filed on May 25, 2011, the entire contents of which are incorporated herein by reference.

### FIELD

Embodiments described herein relate generally to a semiconductor storage device and manufacturing method thereof.

### BACKGROUND

A NAND-type flash memory is known as one of the semiconductor devices. The NAND-type flash memory comprising a plurality of serially connected electrical rewritable nonvolatile memory cells each of which has a floating gate and a control gate to configure a NAND cell unit. Therefore, a unit cell area is small in size, and a large-capacity storage memory is easily acquired.

In the NAND-type flash memory, the plurality of memory cells are NAND-connected through source and drain regions of impurity diffusion layers. In recent years nanofabrication of the memory cell has been progressed, so its source and drain regions are eventually nanofabricated. Accordingly, problems of decreasing sense current and program disturb have been concerned.

### BRIEF DESCRIPTION OF THE DRAWINGS

FIG. 1 is a plan view illustrating a semiconductor storage device according to the first embodiment.

FIG. 2 is a sectional view taken along the line I-I′ of FIG. 1.

FIG. 3 is a sectional view illustrating a configuration of a memory cell of the semiconductor storage device according to the first embodiment.

FIG. 4 is an equivalent circuit which is a part of a memory cell array of the semiconductor storage device according to the first embodiment.

FIGS. 5-10 are sectional views explaining a manufacturing method of the semiconductor storage device according to the first embodiment.

FIG. 11 is a pattern diagram explaining an operation of the semiconductor storage device according to the first embodiment.

FIG. 12 is a sectional view illustrating a configuration of the semiconductor storage device according to a second embodiment.

FIGS. 13-15 are sectional views explaining a manufacturing method of the semiconductor storage device according to the second embodiment.

FIG. 16 is a sectional view illustrating a configuration of the memory cell of the semiconductor storage device according to a third embodiment.

FIGS. 17-23 are sectional views explaining a manufacturing method of the semiconductor storage device according to the third embodiment.

### DETAILED DESCRIPTION

Embodiments of the present invention will be explained below with reference to the accompanying drawings. Note that in the following explanation, the same reference numerals denote elements having the same functions and arrangements.

According to one embodiment of the present invention, there is disclosed a semiconductor storage device comprising: A semiconductor storage device comprising: a semiconductor substrate; and a plurality of electrical rewritable nonvolatile memory cells formed on a surface of the semiconductor substrate, each of the memory cells including a floating gate and a control gate and sharing a source/drain region with an adjacent memory cell, wherein the memory cells are connected serially and configure a NAND cell unit, and the source/drain region includes silicide layer.

### First Embodiment

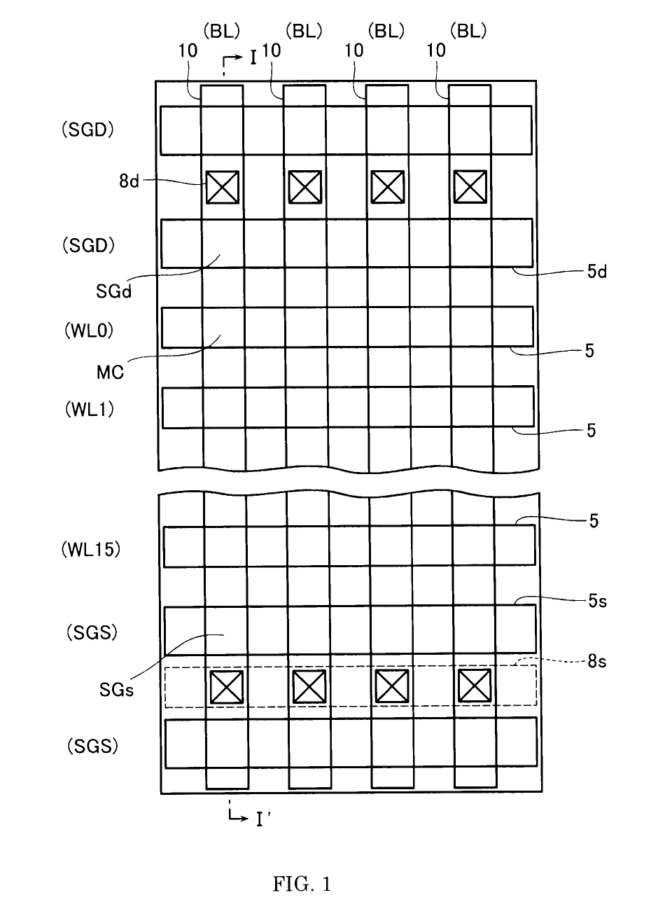

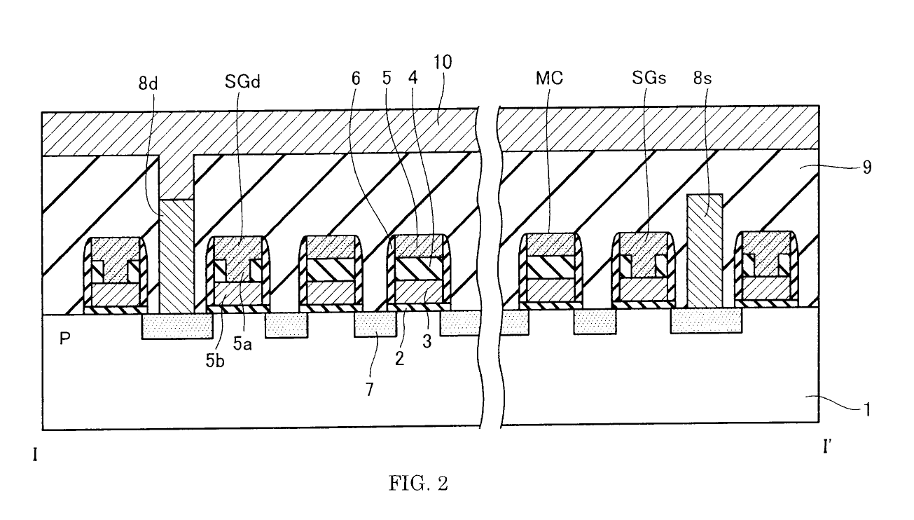

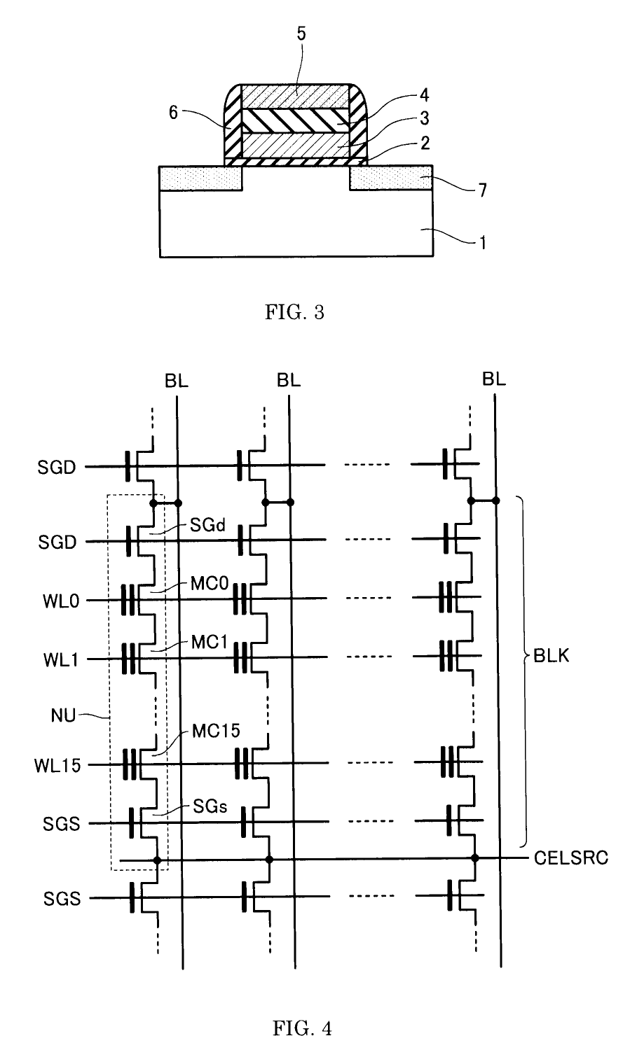

FIG. 1 is a plan view illustrating a memory cell array of the semiconductor storage device according to the first embodiment, FIG. 2 is a sectional view taken along the bit line (BL) direction (a sectional view of I-I′ of FIG. 1.), and FIG. 3 is an enlarged sectional view of one memory cell MC of the memory cell array.

As shown in FIG. 1, the memory cell array comprises a plurality of word lines WL0-WL15, which are disposed parallel to each other extending to a predetermined direction, select gate lines SGD, SGS each of which disposed at the both sides of the word lines WL0-WL15, a plurality of bit lines BL which are parallel to each other extending in a direction orthogonal to the word line WL0-WL15 and the select gate lines SGD, SGS, and a plurality of active regions (not shown) which are disposed parallel to the bit lines BL. A plurality of memory cells MC are formed at crosspoints between the word lines WL0-WL15 and the active areas, and the select gate transistors SGs, SGd are formed at crosspoints between the select gate lines SGD, SGS and the active areas.

FIG. 2 illustrates the sectional view taken along the bit line BL. The plurality of the memory cells MC are serially arranged on a surface of a p-type semiconductor substrate 1 (ex; P well). The select gate transistors SGs and SGd are formed respectively in a source side and a drain side of the plurality of the memory cells MC. The memory cell MC, as shown in FIG. 3, has a gate structure fabricated on the semiconductor substrate 1 including a tunneling insulating layer 2, a floating gate (charge storage layer) 3, an inter-gate insulating layer (block insulating layer) 4, and a control gate 5. A sidewall of the gate structure is covered with a sidewall insulating layer 6. Each of the adjacent memory cells MC shares a source/drain region 7 therebetween, and the source/drain region 7 includes silicide in the embodiment. A source/drain region 7 of the select gate transistors SGs and SGd also includes silicide. Each of the control gates 5 of the memory cells MC is configured to be one of the word lines WL. Each of upper gates 5a of the select gate transistors SGs, SGd is configured to be one of the select gate lines SGS, SGD. The word lines WL and the select gate lines SGS, SGD are also formed of silicide. Each of the floating gates 3 of the memory cells MC and each of lower gates 5b of the select gate transistors SGs, SGd include polysilicon layers, respectively. Thus, a polysilicon layer is used for the floating gate 3, however, metal materials such as tungsten (W) and aluminium (Al) can also be used.

An interlayer insulating layer 9 is disposed so as to cover the memory cells MC, and a bit line (BL) 10 is formed on the interlayer insulating layer 9. A common source line (CELSRC) 8s connecting the sources of NAND cell units in common is buried in the interlayer insulating layer 9, and a bit line contact plug 8d is buried in with, for example, the same conductive material as the common source line. The bit line 10 is connected to the source/drain region 7 formed adjacent to a select gate transistor SG through a bit line contact plugs 8d.

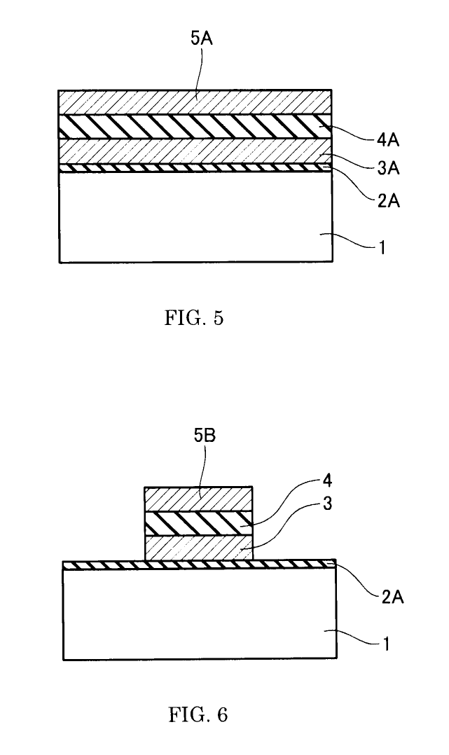

FIG. 4 illustrates an equivalent circuit of the memory cell array. A NAND cell unit NU has a plurality of memory cells MC0-MC15 which are serially connected each other and the select gate transistors SGd, SGs which are disposed at the both ends of the memory cells MC0-MC15. A memory cell block BLK as an erase unit has a plurality of the NAND cell units NU disposed in the word line WL direction. The plurality of NAND cell units NU have the word lines WL and the select gate lines SGS, SGD. One of the word lines WL connects the memory cells MC in common in the word line WL direction. One of the select gate lines SGS, SGD connects the select gate transistors SGd, SGs in common in the word line WL direction. A plurality of the memory cell blocks BLK are arranged in a bit line BL direction in the memory cell array.

An operation of the semiconductor storage device is explained below according to the embodiment.

In the memory cell MC according to the embodiment, because silicide (metal layer) is used for the source/drain region 7, unlike using an impurity diffusion layer instead, a schottky barrier junction is formed at the interface with the semiconductor substrate 1. During a reading operation, electrons from the source/drain region 7 are injected into the channel region and flow towards to the following source/drain region 7 if a voltage exceeding the threshold of the floating gate 3 is applied to the control gate 5 of a selected memory cell MC.

If the source/drain region 7 is formed of the impurity diffusion layer, there may be a problem that the impurity diffusion layer width may get narrower along with the nanofabrication of an element, enough electrons may not be applied to, and a resulting increased resistance may prevent enough sense current from flowing to the source/drain region 7 during the reading operation. In particular, this cause an increased threshold of the floating gate 3, as well as a decreased sense current affected by the trapped electrons at the interface between the semiconductor and the oxide layer as described above. This cause a read and program disturb of data.

There is another possibility to trigger a problem that the impurity diffusion layer region is enlarged by subsequently performed heat treatment to cause a short-channel effect.

On that point, according to the semiconductor storage device of the embodiment, since silicide is used for the source/drain region 7, it is less likely to cause a decreased sense current, program disturb due to the electron trap, and problems by the short channel effect.

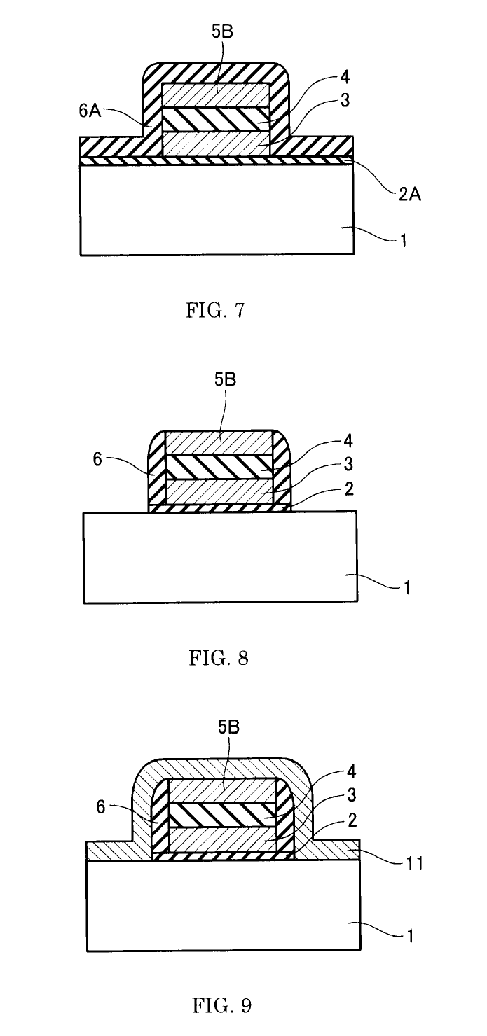

Referring to FIGS. 5-10, a manufacturing method of the semiconductor storage device according to the embodiment will be explained below.

As shown in FIG. 5, an insulating layer 2A as a tunneling insulating layer 2 is formed on the semiconductor substrate 1, a floating gate layer 3A as a floating gate 3 is formed on the insulating layer 2A, a insulating layer 4A as an inter-gate insulating layer 4 is formed on the floating gate layer 3A and a control gate layer 5A as a control gate 5 is formed on the insulating layer 4A. In other words, the insulating layer 2A, the floating gate layer 3A, the insulating layer 4A, and the control gate layer 5A are sequentially stacked on the semiconductor substrate 1. A material such as polysilicon is applicable for the floating gate layer 3A and the control gate layer 5A, and is deposited by the CVD.

Etching is performed to a laminated body including the floating gate layer 3A, the insulting layer 4A and the control gate layer 5A using a mask (not shown). Hence, as shown in FIG. 6, the floating gate 3, inter-gate insulating layer 4 and the control gate 5B are formed and the insulating layer 2A is exposed. As shown in FIG. 7, an oxide layer 6A as a sidewall insulating layer 6 is deposited on the gate structure and the exposed insulating layer 2A by a process such as CVD. As shown in FIG. 8, anisotropic etching is performed while leaving a sidewall insulating layer 6 formed on the sidewall portion of floating gate 3, the inter-gate insulating layer 4 and the control gate 5B. Then, the oxide layer 6A of the upper surface of the control gate 5B is removed, and the oxide layer 6A and the insulating layer 2A are removed except a portion where the gate structure and the sidewall are formed. With this process, a surface of the semiconductor substrate 1 and an upper surface of the control gate 5B between the memory cells MC are exposed, and the tunneling insulating layer 2 is formed.

As shown in FIG. 9, a metal layer 11 is deposited such that it covers the exposed surface of the semiconductor substrate 1, a sidewall insulating layer 6 and the upper surface of the control gate 5B. The metal layer 11 may be made of Nickel (Ni); however, Cobalt (Co), Tungsten (W), Titanium (Ti), and Molybdenum (Mo) may also be used. Heat treatment is performed as shown in FIG. 10 to allow a source and drain portion in the surface of the semiconductor substrate 1 and the control gate 5B to be self-aligned silicide (salicide) layer. With the heat treatment, the salicided source/drain region 7 and the salicided control gate 5 are formed. However, the floating gate 3 is not silicided since it is protected by the inter-gate insulating layer 4 and the sidewall insulating layer 6. Then the memory cell MC is formed by removing the metal layer according to the embodiment.

In the embodiment, it is possible to prevent degradation of the floating gate 3 and short that may occur between the floating gate 3 and the semiconductor substrate 1, and the floating gate 3 and the control gate 5.

### Second Embodiment

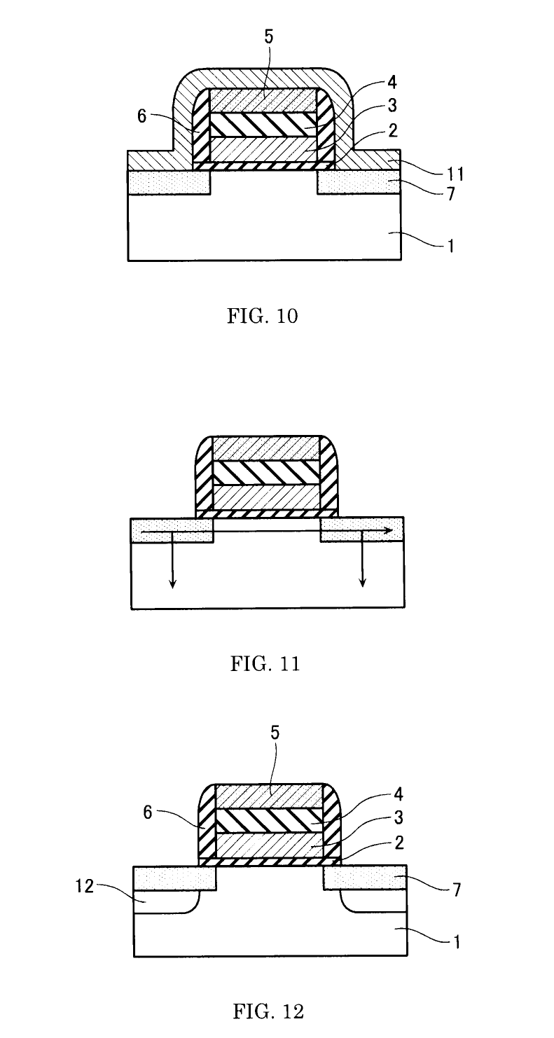

In the first embodiment, because silicide is used for the source/drain region 7, leak current is likely to flow through the semiconductor substrate 1, as indicated by arrows in FIG. 11, if a voltage exceeding a predetermined voltage level beyond the schottky barrier is applied between the source/drain region 7 and the semiconductor substrate 1.

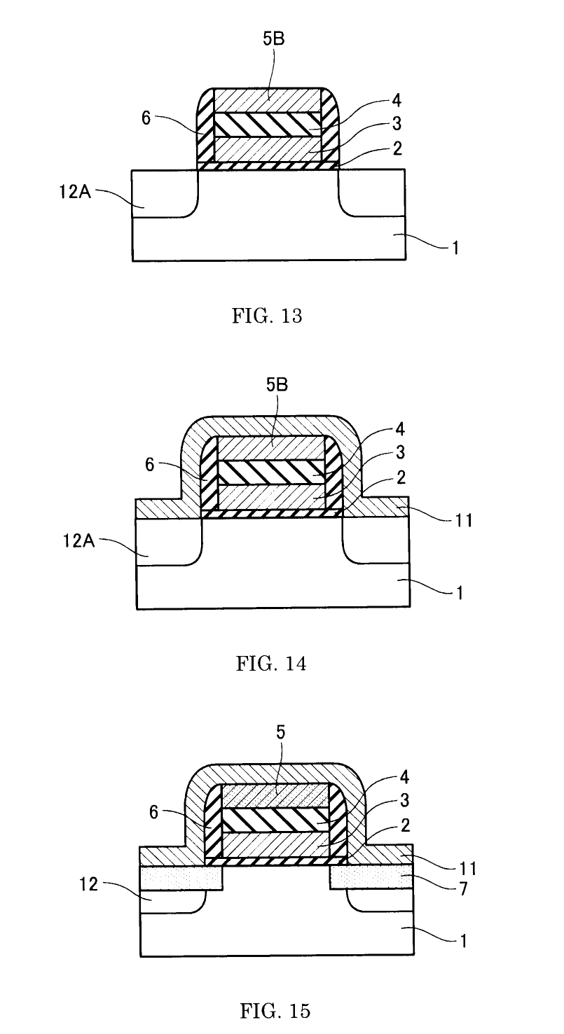

FIG. 12 is a sectional view illustrating a configuration of the memory cell of the semiconductor storage device according to the second embodiment. The memory cell according to the embodiment is basically the same as that of the first embodiment; however, it differs in that the memory cell further has a n-type diffusion layer 12 used silicon below the source/drain region 7.

The n-type diffusion layer 12 is disposed below the source/drain region 7 formed of silicide in the embodiment. Accordingly, a depletion layer is formed at the interface between the n-type diffusion layer and the p-type semiconductor substrate 1 if the voltage exceeding a predetermined voltage level is applied between the source/drain region 7 and the semiconductor substrate 1, such that the depletion layer can suppress leak current by surrounding the whole source/drain region 7 therewith.

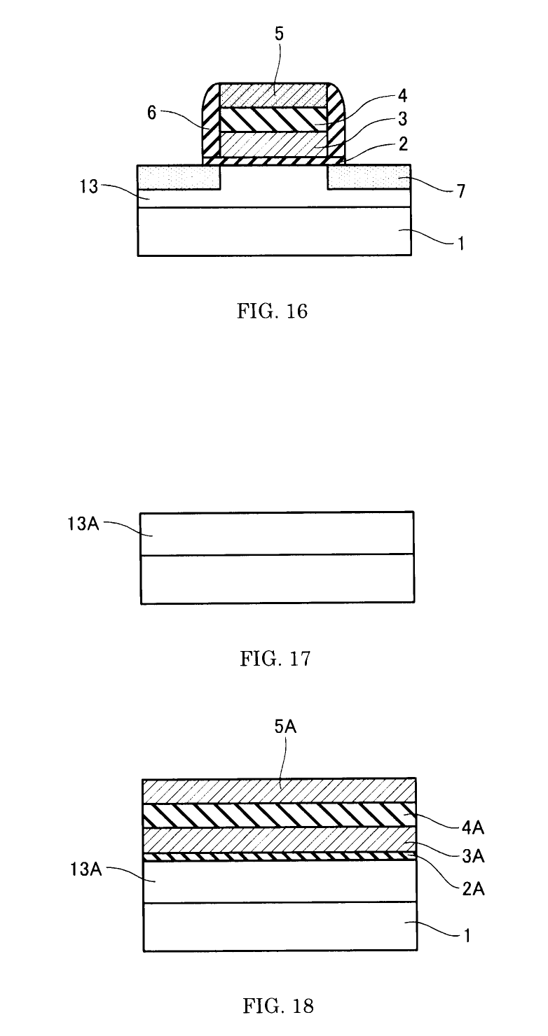

Referring to FIGS. 13-15, a manufacturing method of the semiconductor storage device according to the embodiment will be explained below.

The manufacturing processes of the semiconductor storage device explained until FIG. 8 according to the present embodiment are the same as that of the first embodiment. Later in the process, as shown in FIG. 13, ion implantation is performed with impurities such as arsenic and phosphoric into the source and drain portion in the semiconductor substrate 1 by using a stack structure and the sidewall insulating layer 6 as a mask, wherein the stack structure including the floating gate 3, inter-gate insulating layer 4 and the control gate 5B, to form a n-type diffusion layer 12A. The n-type diffusion layer 12A is formed deeper than the source/drain region 7 which will be later formed, relative to the surface of the semiconductor substrate.

As illustrated in FIG. 14, the metal layer such as Ni is deposited in order to cover the surface of the n-type diffusion layer 12A, the sidewall insulating layer 6 and the control gate 5B. Then, as shown in FIG. 15, heat treatment is performed such that the entire control gate 5B and the source and drain portion in the surface of the n-type diffusion layer 12A to be salicided. With the heat treatment, the salicided source/drain region 7, the n-type diffusion layer 12 and the salicided control gate 5 are formed. However, the floating gate 3 is not salicided because it is protected by the inter-gate oxide layer 4 and the insulating layer 6. Then the memory cell MC is formed by removing the metal layer 11 according to the embodiment.

### Third Embodiment

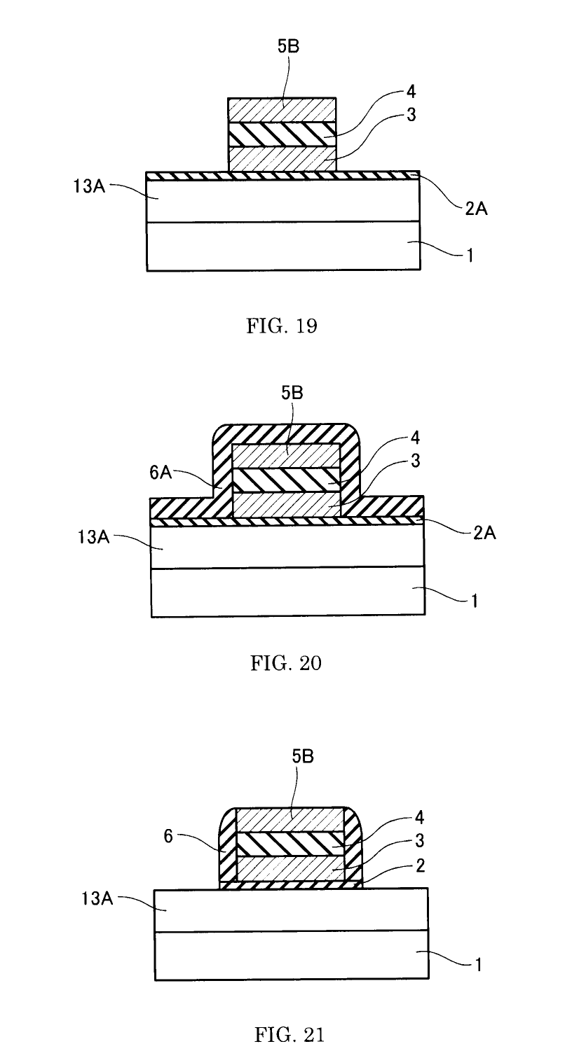

The semiconductor storage device according to the third embodiment is explained below. FIG. 16 illustrates the configuration of the semiconductor storage device according to the embodiment. The semiconductor storage device according to the embodiment is basically the same as that of the first embodiment; however, it differs in that a silicon germanium (SiGe) layer 13 is formed in the upper portion of the silicon substrate where the memory cell is formed. In the semiconductor storage device according to the embodiment, a drain current is increased by the silicon germanium (SiGe) layer 13, and thereby it can suppress leak current flowing into the semiconductor substrate 1.

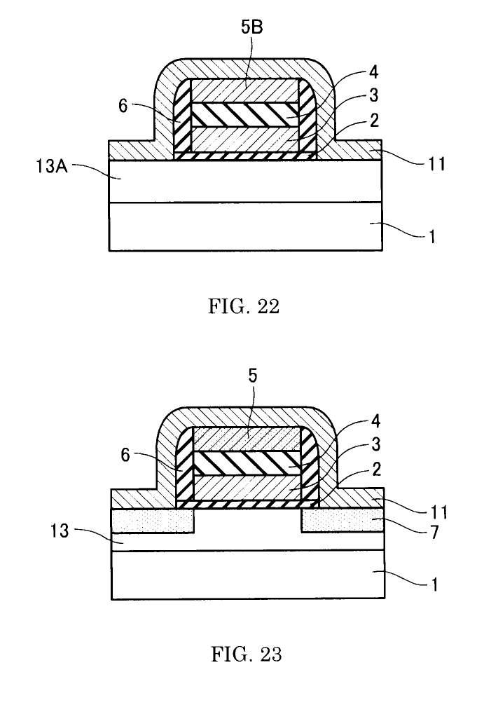

Referring to FIGS. 17-23, a manufacturing method of the semiconductor storage device according to the embodiment will be explained below.

As illustrated in FIG. 17, germanium (Ge) ion is implanted into the upper portion of the semiconductor substrate 1 to form a silicon germanium layer 13A. As illustrated in FIG. 18, the insulating layer 2A as the tunneling insulating layer 2, the floating gate layer 3A as the floating gate 3, the insulating layer 4A as the inter-gate insulating layer 4, and the control gate layer 5A as the control gate 5 are sequentially stacked on the silicon germanium layer 13A. A material such as polysilicon is applicable for the floating gate layer 3A and the control gate layer 5A, and is deposited by the CVD.

Etching is performed to the laminated body including the floating gate layer 3A, the insulting layer 4A and the control gate layer 5A using a mask (not shown). Hence, as shown in FIG. 19, the floating gate 3, inter-gate insulating layer 4 and the control gate 5B are formed and the insulating layer 2A is exposed. As illustrated in FIG. 20, the oxide layer 6A as the sidewall insulating layer 6 is deposited by a process such as CVD. As shown in FIG. 21, anisotropic etching is performed so as to remove the oxide layer 6A and the insulating layer 2A except the sidewall portion on which the floating gate 3, the inter-gate insulating layer 4 and the control gate 5B are deposited, to form the sidewall insulating layer 6 and the tunneling insulating layer 2 and to expose the silicon germanium layer 13A.

As illustrated in FIG. 22, the metal layer such as Ni is deposited such that it covers the exposed surface of the silicon germanium layer 13A, the sidewall insulating layer 6 and the upper surface of the control gate 5B. As illustrated in FIG. 23, heat treatment is performed such that the entire control gate 5B and the source and drain portion in the surface of the silicon-germanium layer 13A to be salicided. With the heat treatment, the salicided source/drain region 7 and the salicided control gate 5 are formed. However, the floating gate 3 is not salicided since it is protected by the inter-gate insulating layer 4 and the sidewall insulating layer 6. Then the memory cell MC is formed by removing the metal layer according to the embodiment.

While certain embodiments have been described, these embodiments have been presented by way of example only, and are not intended to limit the scope of the inventions. Indeed, the novel devices described herein may be embodied in a variety of other forms; furthermore, various omissions, substitutions and changes in the form of the embodiments described herein may be made without departing from the spirit of the inventions. The accompanying claims and their equivalents are intended to cover such forms or modification as would fall within the scope and spirit of the inventions.

What is claimed is:

1. A semiconductor storage device comprising:
a semiconductor substrate; and
a plurality of electrical rewritable nonvolatile memory cells formed on a surface of the semiconductor substrate, each of the memory cells including a charge storage layer and a control gate and sharing a source/drain region with an adjacent memory cell,
wherein the memory cells are connected serially and configure a NAND cell unit, and the source/drain region includes silicide layer.

2. The semiconductor storage device according to claim 1, wherein the control gate includes silicide.

3. The semiconductor storage device according to claim 1 further comprising an impurity diffused layer below the source/drain region in the semiconductor substrate.

4. The semiconductor storage device according to claim 3, wherein a conductive type of the impurity diffused layer is different from that of the semiconductor substrate.

5. The semiconductor storage device according to claim 2 further comprising the impurity diffused layer below the source/drain region in the semiconductor substrate.

6. The semiconductor storage device according to claim 5, wherein a conductive type of the impurity diffused layer is different from that of the semiconductor substrate.

7. The semiconductor storage device according to claim 1 further comprising a silicon germanium layer formed on the surface of the semiconductor substrate, wherein the source/drain region is formed in the surface of the silicon germanium layer.

8. The semiconductor storage device according to claim 2 further comprising the silicon germanium layer formed on the surface of the semiconductor substrate, wherein the source/drain region is formed in the surface of the silicon germanium layer.

9. The semiconductor storage device according to claim 1, wherein the NAND cell unit has a select gate transistor connected to an end portion of the serially connected nonvolatile memory cells, wherein the source/drain region of the select gate transistor include silicide.

10. The semiconductor storage device according to claim 1, wherein each of the nonvolatile memory cells includes a sidewall insulating layer covering sidewalls of the charge storage layer and the control gate.

11. A method of manufacturing a nonvolatile semiconductor memory device comprising:
depositing a first insulating layer as a tunneling insulating layer, a first conductive layer as the charge storage layer, a second insulating layer as the block insulating layer and a second conductive layer as the control gate on a surface of a semiconductor substrate;
selectively etching the first conductive layer, the second insulating layer and the second conductive layer to form a gate structure including the charge storage layer, the block insulating layer and the control gate;
depositing a third insulating layer to form a sidewall insulating layer of the gate structure, and removing the first insulating layer on the surface of the semiconductor substrate except a portion where the gate structure and the sidewall insulating layer are formed to expose the surface of the semiconductor substrate;
depositing a metal layer on the gate structure, the sidewall insulating layer and the surface of the semiconductor substrate with a metal layer; and
performing heat treatment to form a salicide layer at the control gate and the surface of the semiconductor substrate.

12. A method of manufacturing the nonvolatile semiconductor memory device according to claim 11, further comprising:
implanting impurities into the semiconductor substrate using the gate structure and the sidewall insulating as a mask before the depositing the metal layer on the gate structure and the surface of the semiconductor substrate.

13. A method of manufacturing the nonvolatile semiconductor memory device according to claim 12, wherein a conductive type of the impurities is different from that of the semiconductor substrate.

14. A method of manufacturing the nonvolatile semiconductor memory device according to claim 11, further comprising:
providing a silicon substrate as the semiconductor substrate, and
implanting germanium-ion into the surface of the semiconductor substrate, before the depositing the first insulating layer, the first conductive layer, the second insulating layer, and the second conductive layer on the semiconductor substrate.
